(19) United States
(12) Patent Application Publication
(10) Pub. No.: US 2014/0284580 A1
(43) Pub. Date: Sep. 25, 2014

(54) ELECTRON TRANSPORTING COMPOUNDS AND ORGANIC ELECTROLUMINESCENT DEVICES USING THE SAME

(71) Applicant: E-RAY OPTOELECTRONICS TECHONOLOGY CO., LTD., Chung-Li (TW)

(72) Inventors: Banumathy Balaganesan, Chung-Li (TW); Heh-Lung Huang, Chung-Li (TW); Po-Wei Hsu, Chung-Li (TW); Fang-Shih Lin, Chung-Li (TW)

(73) Assignee: E-RAY OPTOELECTRONICS TECHONOLOGY CO., LTD., Chung-Li (TW)

(21) Appl. No.: 14/221,744

(22) Filed: Mar. 21, 2014

Related U.S. Application Data
(60) Provisional application No. 61/804,273, filed on Mar. 22, 2013.

(51) Int. Cl. H01L 51/00; H01L 51/50

(52) U.S. Cl. CPC H01L 51/0054; H01L 51/0072; H01L 51/0002; H01L 51/5096
USPC 257/40; 438/46

(57) ABSTRACT

Disclosed is a novel compound of Formula 1 and an organic electroluminescent device using the same. In Formula 1, X and Y independently represents a hydrogen, an aromatic or a hetero aromatic hydrocarbon having C5 to C10 carbons; X and Y may be the same or different; Ar₁ to Ar₂ each represent a hydrogen, an unsubstituted or substituted aromatic hydrocarbon having C4 to C12 carbons, or an unsubstituted or substituted condensed polycyclic aromatic hydrocarbon having C4 to C12 carbons; Ar₁ to Ar₂ can form a fused aromatic ring system with the adjacent aromatic hydrocarbons. The compound of Formula 1 is present in the electron injection or a transport material, or an exciton blocking layer in the organic light emitting device, and thereby improving the device stability, lowering the operational voltage.

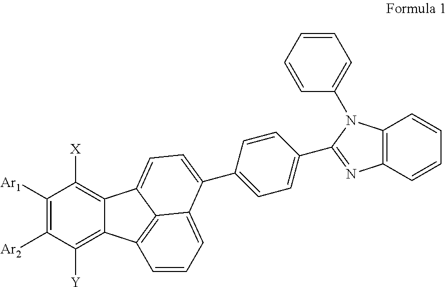

### BACKGROUND OF THE INVENTION

1. Field of the Invention

The present invention relates to organic electroluminescent devices with non-emissive materials, and more specifically, to an organic electroluminescent device with a non-emissive material having a fused ring structure for emitting white lights.

2. Description of Related Art

Organic light-emitting devices (OLED) are gaining attraction in the recent years as the active displays owing to their characteristics such as high brightness, quick refresh rate and wide color gamut and are more suitable for portable electronic applications.

In general, an OLED comprises an anode, a hole transport layer, an emitting layer, an electron transport layer and a cathode, which are deposited one over the other sequentially, by means of vacuum deposition or coating techniques. When a voltage is applied, the anode injects holes and the cathode injects electrons into the organic layer(s). The injected holes migrate to the emitting layer through the hole transporting layer and the electrons migrate to the light emitting layer through the electron transporting layer. In the emitting layer, the holes and electrons recombine to produce excitons. Light is emitted when the exciton relaxes through a photoemissive mechanism.

The reason for manufacturing an organic electroluminescent (EL) display with a multi-layered thin film structure includes stabilization of the interfaces between the electrodes and the organic layers. In addition, in organic materials, the mobility of electrons and holes significantly differ, and thus, if appropriate hole transporting and electron transporting layers are used, holes and electrons can be efficiently transferred to the luminescent layer. Also, if the density of the holes and electrons are balanced in the emitting layer, luminous efficiency can be increased. The proper combination of organic layers described above can enhance the device efficiency and lifetime. However, it has been very difficult to find an organic material that satisfies all the requirements for use in practical display applications.

Tris(8-hydroxyquinoline)aluminum (Alq₃) is one of the widely used electron transporting material; however, it has an intense green emission and devices using the same exhibits higher driving voltages. Therefore, it is crucial to find an electron transporting molecule that has excellent properties compared to the conventional material in all practical aspects, such as high efficiency, reduced driving voltage and operational stability.

Organic small molecules having imidazole groups, oxazole groups and thiazole groups have been frequently reported as materials for electron injection and transportation layers, as described in the literature Chem. Mater. 2004, No. 16, p. 4556.

U.S. Pat. No. 5,645,948 and U.S. Pat. No. 5,766,779 disclose a representative material, 1,3,5-tris(1-phenyl-1H-benzimidazol-2-yl)benzene (TPBI), for electron transportation having blue emission. TPBI has three N-phenyl benzimidazole groups, in 1,3,5-substitution sites of benzene and functions both as an electron transporting and an emitting material. However, TPBI has lower operational stability.

U.S. Pat. No. 6,878,469 discloses a compound, wherein the 2-phenyl benzimidazolyl group is linked to the C-2, C-6 positions of anthracene framework. US20080125593, KR20100007143 discloses electron transporting materials comprising imidazopyridyl or benzimidazolyl groups in its molecular skeleton, exhibiting low driving voltage and high efficiency. However, these materials also lack operational stability.

Fluoranthene derivatives are well known in the art as being useful as light emitting compounds, have been disclosed in JP2002069044, JP2005320286, US20070243411, WO2008059713, WO2011052186. U.S. Pat. No. 7,879,465 and U.S. Pat. No. 8,076,009 disclose the use of annulated fluoranthene in the electron injection and electron transporting layers. However, these devices do not have all desired EL characteristics in terms of high luminance, operational stability and reduced driving voltage.

Therefore, an OLED with prolonged the lifetime stability and reduced operational voltages is indeed required.

### SUMMARY OF THE INVENTION

It is an object of the present invention to provide an OLED device with the above desired properties of prolonged the lifetime stability and reduced an operational voltage, and is capable of emitting white lights.

In order to achieve the aforesaid and other purposes, the present invention provides an OLED device including a cathode, an anode, an emitting layer, and a non-emitting electron transporting layer interposed between the cathode and the emitting layer. In one embodiment, the non-emitting electron transporting layer contains a compound of Formula 1 below at a concentration ranging from 25% to 90%.

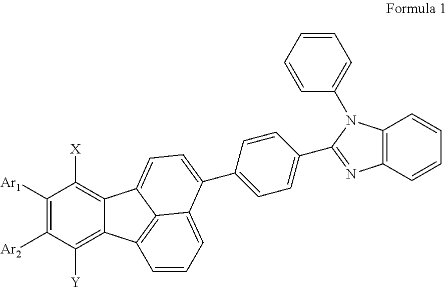

In Formula 1, X and Y independently represents a hydrogen, an aromatic or a hetero aromatic hydrocarbon having C5 to C10 carbons; X and Y may be the same or different; Ar₁ to Ar₂ each represents a hydrogen, an unsubstituted or substituted aromatic hydrocarbon having C4 to C12 carbons from, or an unsubstituted or substituted condensed polycyclic aromatic hydrocarbon having C4 to C12 carbons; Ar₁ to Ar₂ may form a fused aromatic ring system with the adjacent aromatic hydrocarbons.

In another embodiment, the OLED further includes an organic layer at a thickness of between 1 nm and 500 nm.

In a further embodiment, the OLED further includes an electron transport layer, an electron injection layer, a light emitting layer, a hole block layer or electron block layer, in which the compound represented by Formula 1 is contained.

In yet another embodiment, the OLED further comprises an n-dopant material or a fluorescent or phosphorescent emitter to be used in combination with the compound represented by Formula 1.

### BRIEF DESCRIPTION OF THE DRAWINGS

FIG. 1 is a cross-sectional view illustrating one example of an organic light emitting device according to an embodiment of the present invention;

FIG. 2 is a cross-sectional view illustrating an example of an organic light emitting device according to another embodiment of the present invention;

FIG. 3 is a cross-sectional view illustrating an example of an organic light emitting device according to yet another embodiment of the present invention;

FIG. 4 shows the electroluminescent spectrum of a blue fluorescent organic electroluminescent device according to the present invention; and

FIG. 5 shows the electroluminescent spectrum of a green phosphorescent organic electroluminescent device according to the present invention.

### DETAILED DESCRIPTION OF THE PREFERRED EMBODIMENTS

The following specific embodiments are provided to illustrate the disclosure of the present invention. These and other advantages and effects can be easily understood by those skilled in the art after reading the disclosure of this specification.

A compound for an organic electroluminescent device according to this invention is represented Formula (I). In the Formula (I), X and Y independently represents a hydrogen, an aromatic or a hetero aromatic hydrocarbon having C5 to C10 carbons from; X and Y may be the same or different; Ar₁ to Ar₂ each represents a hydrogen, an unsubstituted or substituted aromatic hydrocarbon having C4 to C12 carbons, or an unsubstituted or substituted condensed polycyclic aromatic hydrocarbon having C4 to C12 carbons; Ar₁ to Ar₂ can form a fused aromatic ring system with the adjacent aromatic hydrocarbons.

Preferable examples of the compounds represented by the aforementioned Formula (I) are shown below (A to L) but not limited to.

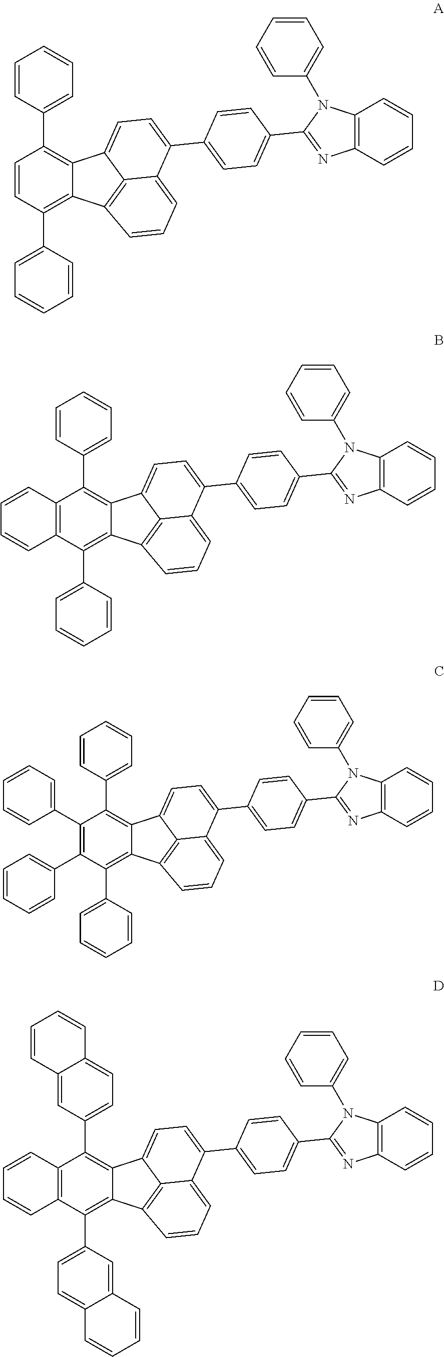 [SMILES: c1ccc(-c2ccc(-c3ccccc3)c3c2-c2cccc4c(-c5ccc(-c6nc7ccccc7n6-c6ccccc6)cc5)ccc-3c24)cc1 ; c1ccc(-c2c3c(c(-c4ccccc4)c4ccccc24)-c2ccc(-c4ccc(-c5nc6ccccc6n5-c5ccccc5)cc4)c4cccc-3c24)cc1 ; c1ccc(-c2c(-c3ccccc3)c(-c3ccccc3)c3c(c2-c2ccccc2)-c2cccc4c(-c5ccc(-c6nc7ccccc7n6-c6ccccc6)cc5)ccc-3c24)cc1 ; c1ccc(-n2c(-c3ccc(-c4ccc5c6c(cccc46)-c4c-5c(-c5ccc6ccccc6c5)c5ccccc5c4-c4ccc5ccccc5c4)cc3)nc3ccccc32)cc1]

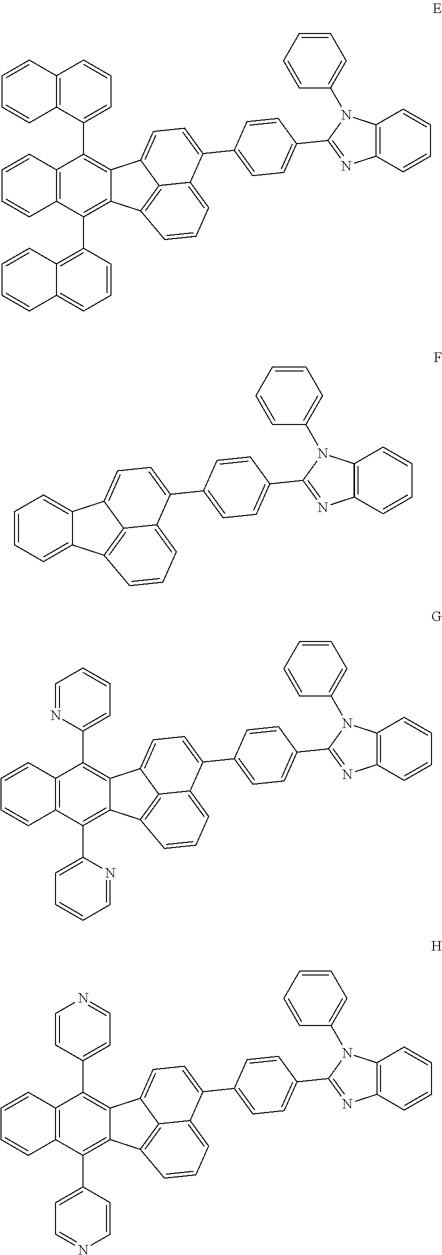 [SMILES: c1ccc(-n2c(-c3ccc(-c4ccc5c6c(cccc46)-c4c-5c(-c5cccc6ccccc56)c5ccccc5c4-c4cccc5ccccc45)cc3)nc3ccccc32)cc1 ; c1ccc(-n2c(-c3ccc(-c4ccc5c6c(cccc46)-c4ccccc4-5)cc3)nc3ccccc32)cc1 ; c1ccc(-n2c(-c3ccc(-c4ccc5c6c(cccc46)-c4c-5c(-c5ccccn5)c5ccccc5c4-c4ccccn4)cc3)nc3ccccc32)cc1 ; c1ccc(-n2c(-c3ccc(-c4ccc5c6c(cccc46)-c4c-5c(-c5ccncc5)c5ccccc5c4-c4ccncc4)cc3)nc3ccccc32)cc1]

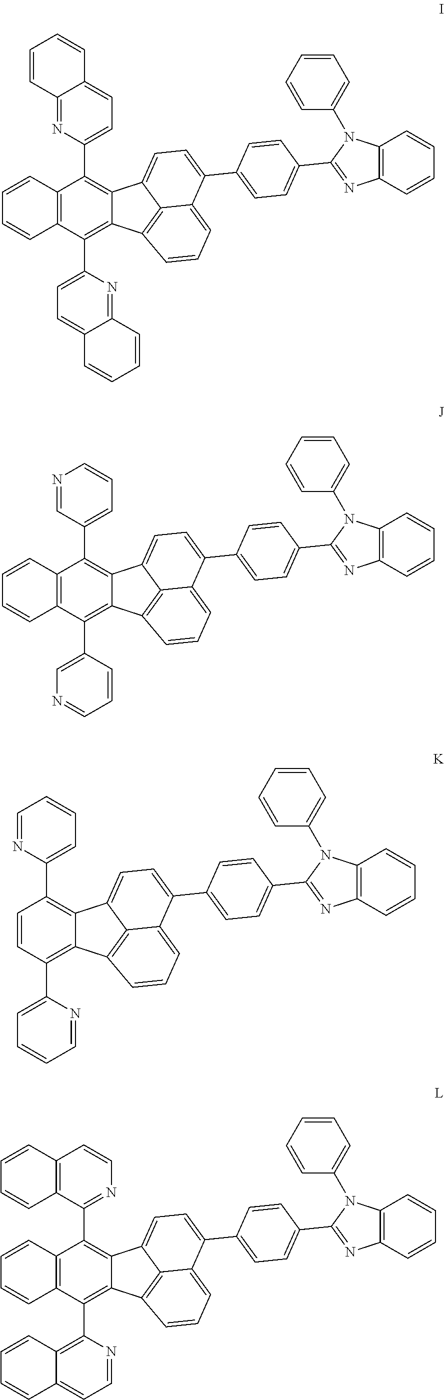 [SMILES: c1ccc(-n2c(-c3ccc(-c4ccc5c6c(cccc46)-c4c-5c(-c5ccc6ccccc6n5)c5ccccc5c4-c4ccc5ccccc5n4)cc3)nc3ccccc32)cc1 ; c1ccc(-n2c(-c3ccc(-c4ccc5c6c(cccc46)-c4c-5c(-c5cccnc5)c5ccccc5c4-c4cccnc4)cc3)nc3ccccc32)cc1 ; c1ccc(-n2c(-c3ccc(-c4ccc5c6c(cccc46)-c4c(-c6ccccn6)ccc(-c6ccccn6)c4-5)cc3)nc3ccccc32)cc1 ; c1ccc(-n2c(-c3ccc(-c4ccc5c6c(cccc46)-c4c-5c(-c5nccc6ccccc56)c5ccccc5c4-c4nccc5ccccc45)cc3)nc3ccccc32)cc1]

Various aryl substituted benzofluoranthenes may be prepared by following similar literature procedures given in Journal of the American Chemical Society 1949, vol. 71 (6), p. 1917; Journal of Nanoscience and Nanotechnology 2008, 8(9), p. 4787. Symmetrical 1,3-diarylisobenzofurans, used as the starting material for the preparation of the benzofluoranthenes were synthesized following the procedure provided in Synlett, 2006, 13, p. 2035. They were then converted to the corresponding bromo analogues of aryl substituted fluoranthenes adapting similar procedures given in various literatures.

Suzuki coupling of the brominated fluoranthenes with (4-(1-phenyl-1H-benzo[d]imidazol-2-yl)phenyl)boronic acid has been employed to synthesize compounds represented by Formula 1, as shown below.

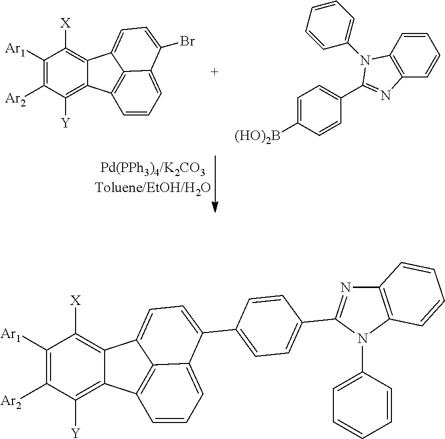

The compound represented by Formula 1 may be included in an organic layer of an organic electroluminescent device (EL). Therefore, the organic electroluminescent device of the present invention has at least one organic layer interposed between an anode and a cathode piled one upon another on a substrate, and the organic layer includes the aforementioned compound represented by the Formula 1 as described earlier. Here the organic layer may be an emitting layer, a hole block layer, an electron transport layer, electron injection layer or a hole transport layer. The organic layer including the compound represented by the Formula 1 may preferably be included in the electron transport/injection layer and in combination with electrically injecting dopants (n/p type).

Electrically conducting (n/p type) dopants to be used in the electron transport layer are preferably organic alkali/alkaline metal complexes, oxides, halides, carbonates, phosphates of alkali/alkaline group metals containing at least one metal selected from lithium and cesium. Such organic metal complexes are known in the aforementioned patent documents and elsewhere and a suitable complex can be selected from them and used in this invention.

The content of the aforementioned electrically injecting dopant in the electron transport/electron injection layer is preferably in the range of 25 wt % to 75 wt % .

Further, the compound represented by any of Formula 1 may be included in the layer between emitting layer and electron transport layer. The emitting layer may include fluorescent and phosphorescent dopants and the corresponding fluorescent and phosphorescent host emitters, respectively.

Furthermore, the compounds represented by Formula 1 may be used in the electron injecting/transporting layer or hole blocking layer and/or electron blocking layer.

The structure of the organic electroluminescent device of this invention will be explained with reference to the drawing, but not limited thereto.

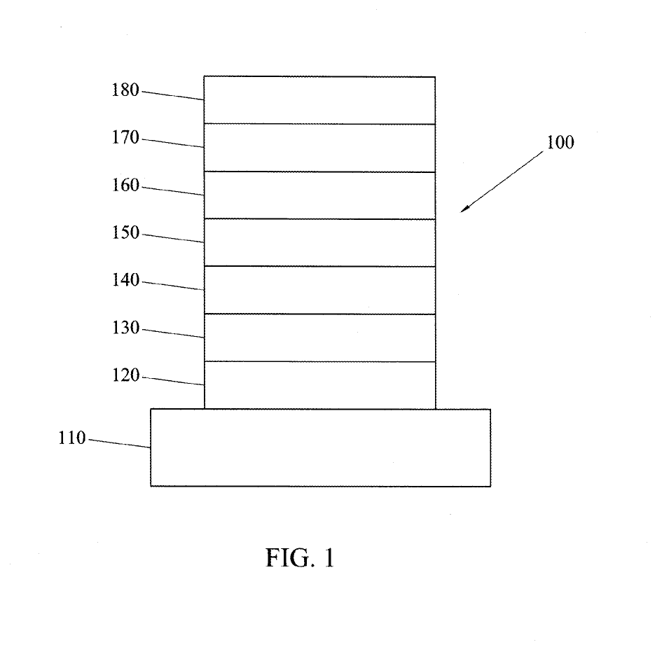

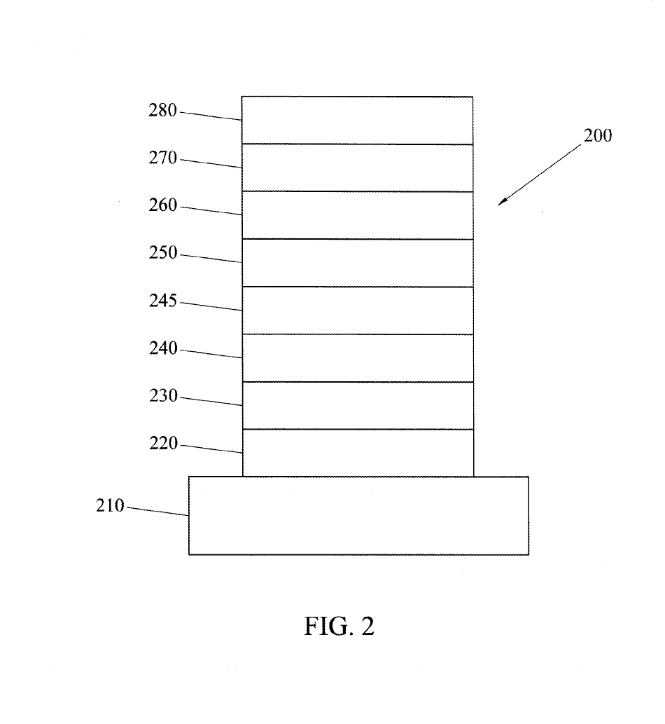

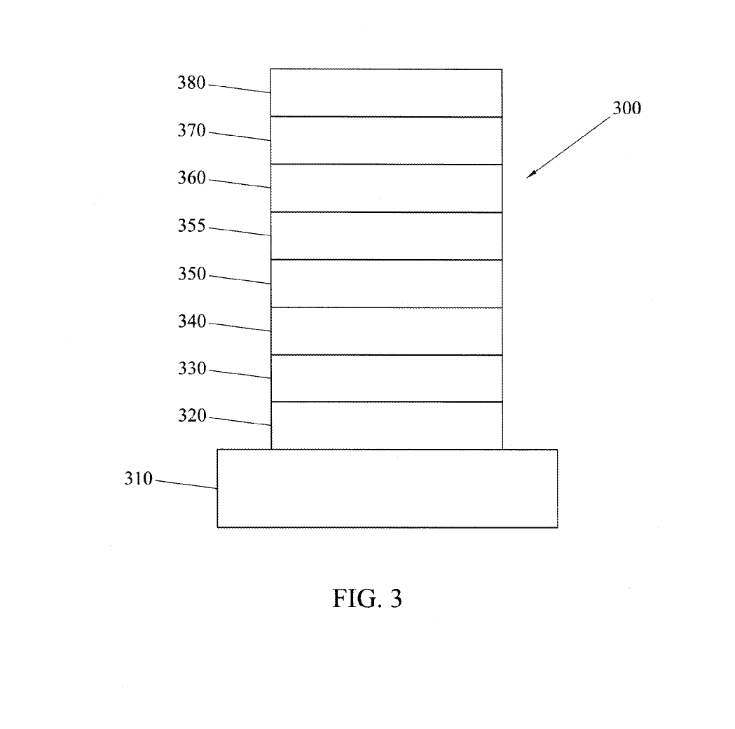

FIG. 1 is a schematic view showing an organic light emitting device according to an embodiment of the present invention. An organic light emitting device 100 includes a substrate 110, an anode 120, a hole injection layer 130, a hole transport layer 140, an emissive layer 150, an electron transport layer 160, an electron injection layer 170, and a cathode 180. The organic light emitting device 100 may be fabricated by depositing the layers described in order. FIG. 2 is a schematic view showing an organic light emitting device according to another embodiment of the present invention, which is similar to FIG. 1, except that an exciton blocking layer 245 is disposed on a hole transport layer 240 and below a light emitting layer 250. FIG. 3 is a schematic view showing an organic light emitting device according to another embodiment of the present invention, which is similar to FIG. 2, except that an exciton blocking layer 355 is disposed on a light emitting layer 350 and below an electron transport layer 360.

It is possible to fabricate an organic light emitting device with a structure that is the reverse of the one shown in FIGS. 1-3. In this case of the reverse structure, a layer or layers may be added or omitted as needed.

Materials used in hole injection layer, hole transport layer, electron blocking layer, hole blocking layer, light emitting layer, electron injecting layer may be selected from those reported in the literature cited elsewhere. For example, an electron-transporting material forming the electron-transporting layer differs from the material forming the light emitting layer and has hole-transporting properties, so as to facilitate the hole mobility in the electron-transporting layer, and to prevent accumulation due to the difference in ionization potential between the light emitting layer and the electron-transporting layer can be prevented.

In addition, U.S. Pat. No. 5,844,363, which is incorporated herein by reference in its entirety, discloses a flexible and transparent substrate-anode combination. An example of a p-doped hole transport layer is m-MTDATA doped with F₄-TCNQ at a molar ratio of 50:1, as disclosed in US Patent Application Publication No. 20030230980, which is incorporated herein by reference in its entirety. An example of an n-doped electron transport layer is BPhen doped with Li at a molar ratio of 1:1, as disclosed in US Patent Application Publication No. 20030230980, which is incorporated herein by reference in its entirety. U.S. Pat. Nos. 5,703,436 and 5,707,745, which are incorporated herein by reference in their entireties, disclose examples of cathodes including compound cathodes having a thin layer of metal such as Mg:Ag with an overlying transparent, electrically-conductive, sputter-deposited ITO layer. The theory and use of blocking layers is described in U.S. Pat. No. 6,097,147 and US Patent Application Publication No. 20030230980, which are incorporated herein by reference in their entireties. Examples of injection layers are provided in US Patent Application Publication No. 20040174116, which is incorporated herein by reference in its entirety. A description of protective layers may be found in US Patent Application Publication No. 20040174116, which is incorporated herein by reference in its entirety.

Structures and materials not specifically described may also be used, such as OLEDs comprised of polymeric materials (PLEDs) such as disclosed in U.S. Pat. No. 5,247,190, which is incorporated herein by reference in its entirety. Further, OLEDs having a single organic layer may be used. OLEDs may be stacked as described in U.S. Pat. No. 5,707,745, which is incorporated herein by reference in its entirety.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated herein by reference in their entireties, organic vapor phase deposition (OVPD), such as described in U.S. Pat. No. 6,337,102, which is incorporated herein by reference in its entirety, and deposition by organic vapor jet printing (OVJP), such as described in U.S. patent application Ser. No. 10/233,470, which is incorporated herein by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated herein by reference in their entireties, and patterning associated with deposition methods such as ink-jet and OVJD. Certainly, other methods may be used. The materials to be deposited may be modified to make them compatible with a particular deposition method.

The compound represented by Formula 1 is capable of being made into an amorphous thin film by means of vacuum deposition method or spin coating method, for organic electroluminescent devices. When the compound is used in any of the organic layers described above, it exhibits a longer lifetime and better thermal stability with high efficiency and low driving voltage.

An organic electroluminescent device of this invention is applicable to a single device, a device with its structure arranged in array, or a device having the anode and the cathode arranged in an X-Y matrix. The present invention significantly improves luminous efficiency and driving stability of an organic electroluminescent device over the conventional devices, when used in combination of phosphorescent dopants in the light emitting layer. Further, the organic electroluminescent device of the present invention can perform better when applied to full-color or multicolor panels, and can emit white lights.

### EXAMPLES

The invention is further illustrated by the following examples in detail for clarifying the characteristics and effectiveness of the present invention. The detailed embodiments are merely used for clarifying the characteristics of the present invention. The present invention is not limited to the particular embodiment illustrated.

### Synthesis Example 1

### Synthesis of Compound B

In a 1 L flask, a mixture of 3-bromo-7,12-diphenylbenzo[k]fluoranthene (20 g), (4(1-phenyl-1H-benzo[d]imidazol-2-yl)phenyl)boronic acid (15.6 g), tetrakis(triphenylphosphine)palladium (2.40 g), toluene (300 ml), ethanol (150 ml) and 2M aqueous solution of potassium carbonate(72.4 ml) were added together, and refluxed for 16 hr. The reaction was quenched with water and the toluene layer was removed and washed with brine and dried with anhydrous sodium sulfate, and the solvent was removed under reduced pressure to yield 2-(4-(7,12-diphenylbenzo[k]fluoranthen-3-yl)phenyl)-1-phenyl-1H-benzo[d]imidazole (compound B, 5.3 g) as a light yellow solid.

¹H NMR (CDCl₃, 6): 7.92 (d, 1H), 7.77(d, 1H), 7.71-7.62 (m, 10H), 7.60-7.55 (m, 4H), 7.55-7.52 (m, 1H), 7.52-7.49 (m, 1H), 7.48-7.44 (m, 2H), 7.43-7.39 (m, 4H), 7.38-7.34 (m, 1H), 7.32-7.25 (m, 5H), 6.64 (d, 2H).

### Synthesis Example 2

### Synthesis of Compound C

3-bromo-7,8,9,10-tetraphenylfluoranthene was synthesized following the procedure cited in New Journal of Chemistry, 2010, 34, p. 2739.

3-bromo-7,8,9,10-tetraphenylfluoranthene (20 g), (4-(1-phenyl-1H-benzo[d]imidazol-2-yl) phenyl)boronic acid (12.88 g), tetrakis(triphenylphosphine)palladium (1.97 g), toluene (300 ml), ethanol (150 ml) and 2M aqueous solution of potassium carbonate (59.8 ml) were added together, and refluxed for 16 hr. The reaction was quenched with water and the toluene layer was removed and washed with brine and dried with anhydrous sodium sulfate, and the solvent was removed under reduced pressure to yield 1-phenyl-2-(4-(7,8,9,10-tetraphenylfluoranthen-3-yl)phenyl)-1H-benzo[d]imidazole (Compound C, 14.6 g) as a light yellow solid.

¹H NMR (CDCl₃, 6): 7.90-7.96 (m, 2H), 7.80 (m, 2H), 7.70 (m, 2H), 7.58 (s, 1H), 7.46-7.55 (m, 12H), 7.30-7.32 (m, 13H),7.22-7.26 (m, 6H).

### Synthesis Example 3

### Synthesis of Compound A

3-bromo-7,10-diphenylfluoranthene was synthesized following the procedure given in the Journal of the American Chemical Society, 1993, 11, p. 11542.

3-bromo-7,10-diphenylfluoranthene (20 g), (4-(1-phenyl-1H-benzo[d]imidazole-2-yl)phenyl)boronic acid (17.40 g), tetrakis(triphenylphosphine)palladium (2.67 g), toluene (300 ml), ethanol (150 ml) and 2M potassium carbonate (80.8 ml) were added together, and refluxed for 16 hr. The reaction was quenched with water and the toluene layer was removed and washed with brine and dried with anhydrous sodium sulfate, and the solvent was removed under reduced pressure to yield 2-(4-(7,10-diphenylfluoranthen-3-yl)phenyl)-1-phenyl-1H-benzo[d]imidazole (compound A, 17.8 g) as a yellow powder.

¹H NMR (CDCl₃, 8): 7.92-7.96 (m, 2H), 7.70-7.80 (m, 4H), 7.58 (s, 1H), 7.53-7.55 (m, 6H), 7.47-7.49 (m, 4H), 7.28-7.32 (m, 9H), 7.22-7.26 (m, 4H).

### Synthesis Example 4

### Synthesis of Compound F

3-bromofluoranthene (20 g), (4-(1-phenyl-1H-benzo[d]imidazol-2-yl)phenyl)boronic acid (26.82 g), tetrakis(triphenylphosphine)palladium (4.11 g), toluene (300 ml), ethanol (150 ml) and 2M Potassium carbonate(124.5 ml) were added together, and stirred at 80° C. for 16 hr. The reaction was quenched with water and the toluene layer was removed and washed with brine and dried with anhydrous sodium sulfate, and the solvent was removed under reduced pressure to yield 2-(4-(fluoranthen-3-yl)phenyl)-1-phenyl-1H-benzo[d]imidazole (compound F, 17.8 g) as a light yellow amorphous solid.

¹H NMR (CDCl₃, 8): 7.90 (m, 2H), 7.79-7.80 (m, 2H), 7.70 (m, 2H), 7.58 (s, 1H), 7.53-7.55 (m, 6H), 7.54 (m, 4H), 7.30 (m, 5H), 7.23-7.28 (m, 11H).

### Examples 1-4

### Fabrication of Organic EL Devices

Prior to use, the substrate was degreased with solvents and cleaned in UV ozone before it was loaded into the evaporation system. The substrate was then transferred into a vacuum deposition chamber for deposition of all other layers on top of the substrate. The following layers were deposited in the following sequence, as shown in FIG. 2, by evaporation from a heated boat under a vacuum of approximately 10⁻⁶ Torr:
a) a hole injecting layer, 20 nm thick, HAT-CN,
b) a hole transporting layer, 60 nm thick, N,N′-di-1-naphthyl-N,N′-diphenyl-4,4′-diaminobiphenyl (NPB);
c) a light emitting layer, 30 nm thick, comprising BH doped with 3% BD by volume;
(BH and BD from eRay optoelectronics Tech Co. Ltd, Taiwan)
e) an electron transporting layer, 20 nm thick, including compound B doped with Liq;
f) an electron injection layer, 1 nm thick, LiF; and
g) a cathode: approximately 150 nm thick, including Al.

Device structure may be denoted as: ITO/HAT-CN (20 nm)/NPB (60 nm)/BH-3% BD (30 nm)/Compound B : Liq (20 nm)/LiF (1 nm)/Al (150 nm).

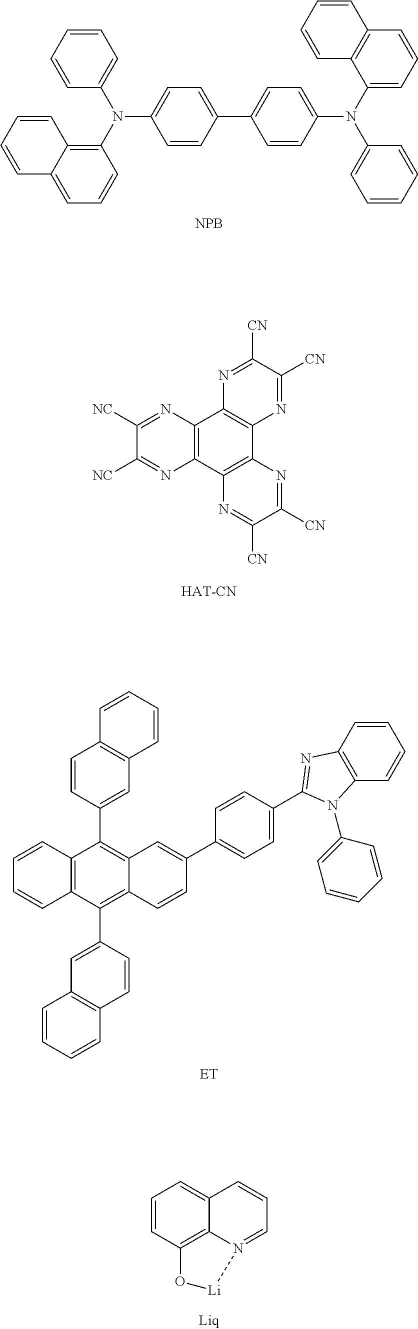

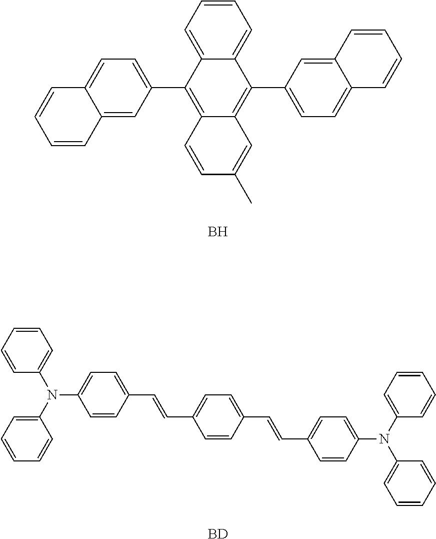

After the deposition of these layers, the device was transferred from the deposition chamber into a dry box for encapsulation, and were subsequently encapsulated using an UV-curable epoxy, and a glass lid containing a moisture getter. The organic EL has an emission area of 3 mm². The organic EL device thus obtained was connected to an outside power source and, upon application of direct current voltage, emission of light with the characteristics shown in Table 2 were confirmed.

The EL characteristics of all the fabricated devices were evaluated using a constant current source (KEITHLEY 2400 Source Meter, made by Keithley Instruments, Inc., Cleveland, Ohio) and a photometer (PHOTO RESEARCH SpectraScan PR 650, made by Photo Research, Inc., Chatsworth, Calif.) at room temperature.

Operational lifetime (or stability) of the devices were tested at the room temperature and at various initial luminance depending on the color of the emitting layer, by driving a constant current through the devices. The color was reported using Commission Internationale de l'Eclairage (CIE) coordinates.

Example 4 was fabricated similar to the layer structure as example 1 except that compound F was used in place of the compound B, in the electron transport layer.

### Comparative Example 1

### Fabrication of Organic EL Device

Organic phosphorescent EL device was fabricated similar to the layer structure as example 1 except that ET was used in place of the compound B, in the electron transport layer. Device structure may be denoted as: ITO/HAT-CN (20 nm)/NPB (60 nm)/BH-3% BD (30 nm)/ET: Lig(20 nm)/LiF (1 nm)/Al (150 nm).

### Examples 5-7

### Fabrication of Green Phosphorescent OLED Device

Green phosphorescent OLED devices were fabricated in the following sequence, as shown in FIG. 2, by evaporation from a heated boat under a vacuum of approximately 10⁻⁶ Torr:
a) a hole injecting layer, 20 nm thick, HAT-CN;
b) a hole transporting layer, 100 nm thick, N,N′-di-1-naphthyl-N,N′-diphenyl-4,4′-diaminobiphenyl (NPB);
c) a light emitting layer, 30 nm thick, comprising GH doped with 14% GD by volume;
(GD-Ir(ppy)₃; GH from eRay optoelectronics Tech Co. Ltd, Taiwan)
e) an electron transporting layer, 30 nm thick, including compound B doped with Liq;
f) an electron injection layer, 1 nm thick, LiF; and
g) a cathode: approximately 150 nm thick, including Al.

Device structure may be denoted as: ITO/HAT-CN (20 nm)/NPB (100 nm)/GH-14% GD (30 nm)/Compound B : Liq (30 nm)/LiF (1 nm)/Al (150 nm).

Examples 6 and 7 were fabricated similar to the layer structure as given in example 5 except that compound A and compound C were used in place of the compound B, in the electron transport layer.

### Comparative Example 2

### Fabrication of Organic EL Device

Organic phosphorescent EL device was fabricated similar to the layer structure as example 5 except that ET was used in place of the compound B, in the electron transport layer. Device structure may be denoted as: ITO/HAT-CN (20 nm)/NPB (100 nm)/GH-14% GD (30 nm)/Compound B: Liq (30 nm)/LiF (1 nm)/Al (150 nm).

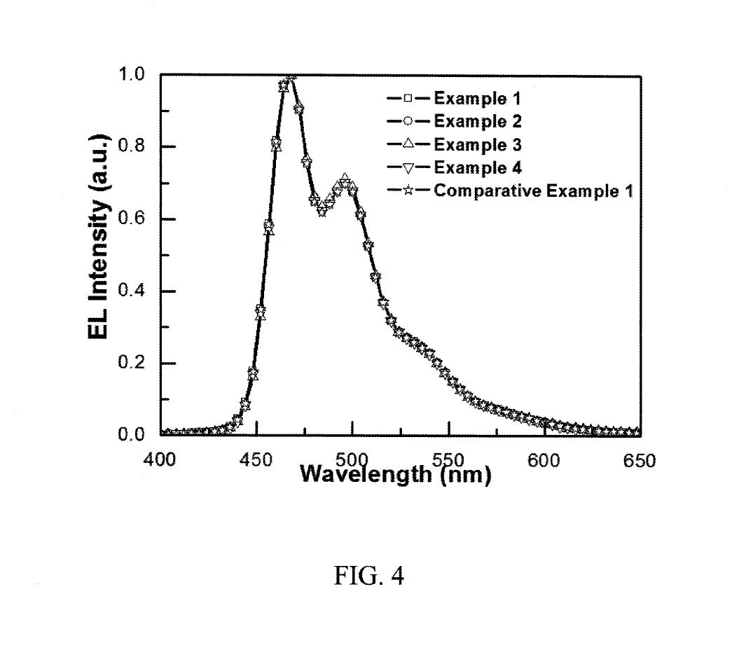

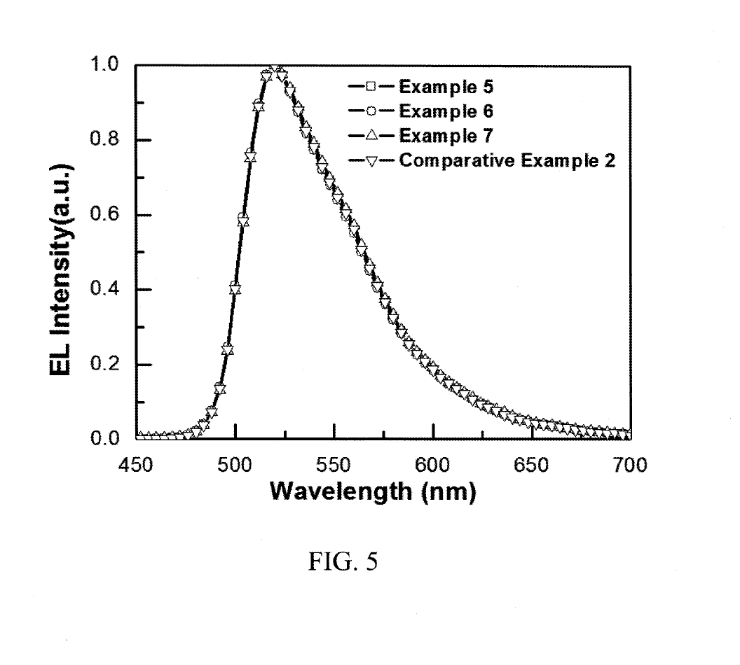

The peak wavelength of emitted light, maximum luminance efficiency, driving voltage and the lifetime stability of the organic EL devices fabricated in the examples are shown in Table 1. EL spectra of the blue fluorescent and green phosphorescent devices fabricated herein are shown in FIG. 4 and FIG. 5.

TABLE 1

| | Compound of | | | Max. | |
|---|---|---|---|---|---|
| | Light Emitting | | | luminance | |
| | Layer, | | Driving | efficiency | |
| | (concen- | Emission | voltage | (cd/A) @ | T₉₀ |
| | tration, %) | peak (nm) | (V) | 10 mA/cm² | (h) |
| Example 1 | Compound B (75) | 468 | 4.72 | 11.06 | 62 ^{a} |
| Example 2 | Compound B (50) | 468 | 4.54 | 11.96 | 47 ^{a} |
| Example 3 | Compound B (25) | 468 | 4.42 | 12.71 | 40 ^{a} |
| Example 4 | Compound F (25) | 468 | 4.46 | 11.81 | 38 ^{a} |
| Compar- | ET (50) | 468 | 4.33 | 12.16 | 34 ^{a} |
| ative | | | | | |
| Example 1 | | | | | |
| Example 5 | Compound B (50) | 524 | 3.90 | 59.59 | 90 ^{b} |
| Example 6 | Compound A (50) | 524 | 3.83 | 57.11 | N/A |
| Example 7 | Compound C (50) | 524 | 3.96 | 58.67 | N/A |
| Compar- | ET (50) | 524 | 3.70 | 58.29 | 60 ^{b} |
| ative | | | | | |
| Example 2 | | | | | |

^{a} Lo = 2000 nits;
^{b} Lo = 10000 nits

The invention shall not be limited by the above described embodiment, method and examples, but by all embodiments and methods within the scope and spirit of the invention as claimed.

### INDUSTRIAL APPLICABILITY

As described above in detail, the organic EL device in which the material for the EL device of the present invention is used is extremely practical because it has high luminous efficiency, high thermal stability, sufficiently low driving voltage and long lifetime. Therefore, the organic EL device of this invention is applicable to flat panel displays, mobile phone displays, light sources utilizing the characteristics of planar light emitters, sign-boards and has a high technical value.

1. An OLED device, comprising: a cathode; an anode; an emitting layer; and a non-emitting electron transporting layer interposed between the cathode and the emitting layer.

2. The OLED device according to claim 1, wherein the non-emitting electron transporting layer comprises a compound of Formula 1 below at a concentration in a range from 25% to 90%: 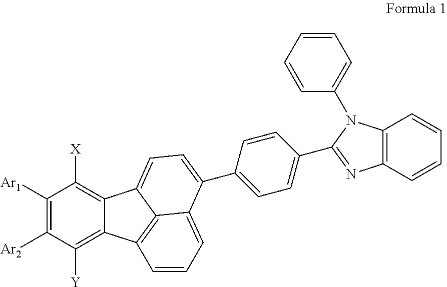
wherein X and Y independently represents a hydrogen, an aromatic or a hetero aromatic hydrocarbon having C5 to C10 carbons; X and Y may be the same or different; Ar₁ to Ar₂ each represent a hydrogen, an unsubstituted or substituted aromatic hydrocarbon having C4 to C12 carbons, or an unsubstituted or substituted condensed polycyclic aromatic hydrocarbon having C4 to C12 carbons; Ar₁ to Ar₂ may form a fused aromatic ring system with the adjacent aromatic hydrocarbons.

3. The OLED device according to claim 1, further comprising an organic layer at a thickness of between 1 nm and 500 nm.

4. The OLED device according to claim 2, further comprising an electron transport layer, an electron injection layer, a light emitting layer, a hole block layer or an electron block layer, in which the compound represented by Formula 1 is contained.

5. The OLED device according to claim 4, further comprising an n-dopant material in combination with the compound represented by Formula 1 in the electron transport layer or in the electron injection layer.

6. The OLED device according to claim 4, further comprising a fluorescent or a phosphorescent emitter in combination with the compound represented by Formula 1 in the light emitting layer.

7. A process for producing an amorphous thin film including the compound represented by Formula 1 according to claim 2.

8. The process according to claim 7, being a vacuum deposition method or a spin coating method.
